(19) United States
(12) Patent Application Publication
(10) Pub. No.: US 2010/0141693 A1
(43) Pub. Date: Jun. 10, 2010

(54) ORGANIC LIGHT-EMITTING DISPLAY APPARATUS AND METHOD FOR DRIVING THE SAME

(76) Inventors: Tae-Joong Lee, Daejeon Metropolitan City (KR); Jae-Dong Park, Daejeon Metropolitan City (KR)

Correspondence Address: MCKENNA LONG & ALDRIDGE LLP, 1900 K STREET, NW, WASHINGTON, DC, 20006, US

(21) Appl. No.: 12/451,067

(22) PCT Filed: Apr. 24, 2008
(86) PCT No.: PCT/KR2008/002329

§ 371 Date: Oct. 23, 2009

(30) Foreign Application Priority Data
Apr. 24, 2007 (KR) 1-2007-0039900

(51) Int. Cl. G09G 5/02; G09G 5/00; G09G 5/10

(52) U.S. Cl. 345/694; 345/211; 345/690; 345/77

(57) ABSTRACT

The present invention provides an organic light-emitting display apparatus and a method of driving the same. The organic light-emitting display apparatus comprises a substrate; scan lines and data lines that are formed on the substrate to cross with each other; stacked organic light-emitting diodes that are connected to the scan lines and the data lines on the substrate and each have two sub-pixels which are stacked, wherein the two stacked sub-pixels are individually driven by one data line; a data driver that is connected to the data lines and applies data signals to the data lines; a scan driver that is connected to the scan lines and applies scan signals to the scan lines; a controller that controls the data driver and the scan driver; and a power supply module that supplies a power supply voltage to the data driver, the scan driver, and the controller.

### TECHNICAL FIELD

The present invention relates to an organic light-emitting display apparatus including stacked organic light-emitting diodes and a method of driving the same.

This application claims priority to and the benefit of Korean Patent Application No. 2007-0039900 filed in the Korean Intellectual Property Office on Apr. 24, 2007, the entire contents of which are incorporated herein by reference.

### BACKGROUND ART

An organic light-emitting display apparatus that includes organic light-emitting diodes (OLED) is a self-emitting display apparatus. Since the organic light-emitting display apparatus has low consumption power, a wide viewing angle, and a fast response speed of pixels, it can display a high-definition moving picture.

As compared with other display technologies, a technology using an organic light-emitting display apparatus has attracted attention as a most promising next-generation flat display technology because it has an advantage in that manufacturing processes are simple and manufacturing costs are low.

In this organic light-emitting display apparatus, organic light-emitting diodes may be divided into passive-matrix (PM) organic light-emitting diodes and active-matrix (AM) organic light-emitting diodes according to driving types thereof.

A passive-matrix organic light-emitting diode (PMOLED) has a simple matrix type in which an anode electrode and a cathode electrode cross each other.

One pixel is formed at an intersection between an anode and a cathode, and each pixel includes sub-pixels for red (hereinafter, simply referred to as R), green (hereinafter, simply referred to as G), and blue (hereinafter, simply referred to as B).

A hole injecting layer (HIL), a hole transporting layer (HTL), an emitting layer (EML), an electron transporting layer (ETL), and an electron injecting layer (EIL), each of which is formed of an organic compound, are formed between the arranged electrodes. These layers may be configured by various combinations.

The passive-matrix organic light-emitting diode has a data line structure of RGBRGB . . . RGB. In this structure, when scan lines are sequentially selected, light is emitted from selected pixels according to signals that are applied to data lines.

In this case, a panel structure and a manufacturing process are simple, but the following problem occurs. If a resolution increases, an area occupied by pixels also increases, and if the length of electrodes increases, resistance of the electrodes also increases, which affects implementation of a uniform color when driving a full-color image and increases power consumption.

For this reason, in order to minimize intervals between the pixels, U.S. Pat. No. 5,917,280 has disclosed a stacked organic light-emitting diode (SOLED) in which organic light-emitting layers for R, G, and B are stacked.

However, according to this technology, there is a problem in that it is difficult to apply the stacked organic light-emitting diode (SOLED) to a matrix-typed display panel due to a unique sub-pixel structure of the stacked organic light-emitting diode. That is, it is difficult to manufacture a matrix-typed display panel where the stacked organic light-emitting diode (SOLED) is applied, and a lot of problems should be resolved to drive the matrix-typed display panel.

### DISCLOSURE OF INVENTION

### Technical Problem

An object of the present invention is to provide an organic light-emitting display apparatus and a method of driving the same that can individually drive two sub-pixels constituting one stacked organic light-emitting diode.

### Technical Solution

The present invention provides an organic light-emitting display apparatus. The organic light-emitting display apparatus comprises a substrate; scan lines and data lines that are formed on the substrate to cross with each other; stacked organic light-emitting diodes that are connected to the scan lines and the data lines on the substrate and each have two sub-pixels which are stacked, wherein the two stacked sub-pixels are individually driven by one data line; a data driver that is connected to the data lines and applies data signals to the data lines; a scan driver that is connected to the scan lines and applies scan signals to the scan lines; a controller that controls the data driver and the scan driver; and a power supply module that supplies a power supply voltage to the data driver, the scan driver, and the controller.

The present invention provides a method of driving an organic light-emitting display apparatus that allows stacked organic light-emitting diodes each having the two sub-pixels, which are stacked, to emit light by a scan driver outputting scan line driving signals for sequentially selecting scan lines and a data driver outputting data line driving signals for outputting data of the selected scan lines to the data lines, wherein the two sub-pixels, which are stacked, are individually driven by one data line.

### ADVANTAGEOUS EFFECTS

According to the present invention, a new passive-matrix organic light-emitting display apparatus or active-matrix organic light-emitting display apparatus where stacked organic light-emitting diodes (SOLED) each having two sub-pixels are used and a method of driving the same are provided.

When a combination of light-emitting colors of four sub-pixels is RGBW on the basis of the four sub-pixels, power consumption can be greatly reduced, and when a combination of light-emitting colors of the four sub-pixels is RBGB, it is excellent in terms of a life span and efficiency of a unit pixel.

According to the present invention, an organic light-emitting display apparatus and a method of driving the same are provided, which can effectively increase the number of pixels per unit area as compared with a passive-matrix organic light-emitting display apparatus and an active-matrix organic light-emitting display apparatus in the related art, when implementing full-color moving picture quality.

### BRIEF DESCRIPTION OF THE DRAWINGS

FIG. 1 is a block diagram illustrating a driving module that drives a full-color passive-matrix organic light-emitting display panel (PMSOLED panel) that includes stacked organic light-emitting diodes (SOLED) according to the present invention.

FIG. 2 is a block diagram illustrating a partial region of a full-color passive-matrix organic light-emitting display panel (PMSOLED panel) that includes stacked organic light-emitting diodes (SOLED) according to the present invention.

FIG. 3 is a timing chart illustrating a process of driving sub-pixels of a stacked organic light-emitting diode (SOLED) according to the present invention.

FIG. 4 is a diagram illustrating a structure of a stacked organic light-emitting diode (SOLED) according to the present invention.

FIG. 5 is a diagram illustrating a structure of a full-color pixel that uses a stacked organic light-emitting diode (SOLED) according to the present invention.

### BEST MODE FOR CARRYING OUT THE INVENTION

An organic light-emitting display apparatus according to an embodiment of the present invention comprises a substrate; scan lines and data lines that are formed on the substrate to cross with each other; stacked organic light-emitting diodes that are connected to the scan lines and the data lines on the substrate and each have two sub-pixels which are stacked, wherein the two stacked sub-pixels are individually driven by one data line; a data driver that is connected to the data lines and applies data signals to the data lines; a scan driver that is connected to the scan lines and applies scan signals to the scan lines; a controller that controls the data driver and the scan driver; and a power supply module that supplies a power supply voltage to the data driver, the scan driver, and the controller.

The stacked organic light-emitting diode comprises the two sub-pixels, which are stacked, having a first electrode, a second electrode, an intermediate electrode located between the first and second electrodes, a first organic material layer located between the first electrode and the intermediate electrode, and a second organic material layer located between the intermediate electrode and the second electrode.

That is, a first sub-pixel comprises the first electrode, the first organic material layer, and the intermediate electrode. And a second sub-pixel comprises the intermediate electrode, the second organic material layer, and the second electrode.

In this case, the first electrode may be formed on a first transparent substrate, and a second transparent substrate may be formed on the second electrode. Each of the first and second transparent substrates is preferably composed of a glass substrate, but the present invention is not limited thereto.

Each of the first organic material layer and the second organic material layer may include a hole injecting layer (HIL), a hole transporting layer (HTL), an emitting layer (EML), and an electron transporting layer (ETL).

One of the first and second sub-pixels that are included in the stacked light-emitting diode having the above-described structure may operate by a forward bias and the other may operate by a reverse bias.

For example, in the case where the first electrode is an anode electrode, the second electrode is a cathode electrode, and the intermediate electrode is a common data electrode of the stacked first and second sub-pixels, if the first sub-pixel operates by a forward bias, the second sub-pixel operates by a reverse bias, and if the first sub-pixel operates by a reverse bias, the second sub-pixel operates by a forward bias.

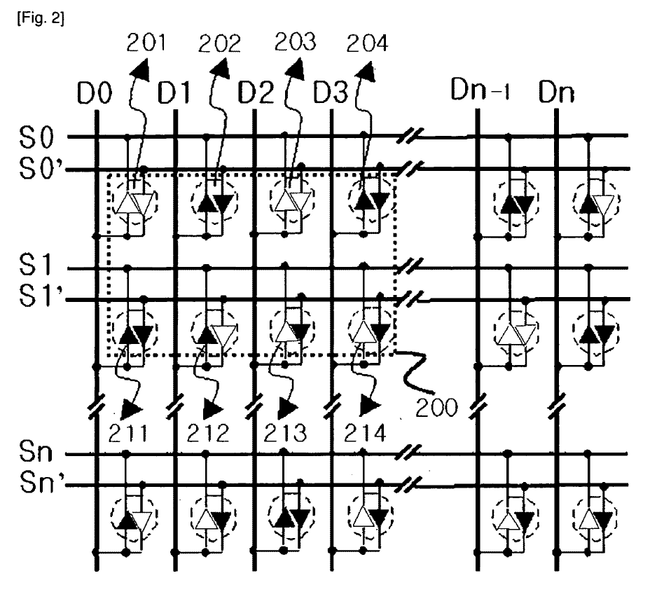

The stacked organic light-emitting diodes each having first and second sub-pixels may be connected to the data lines D₀ to Dn and the scan lines S₀ to Sn′, which cross each other (refer to FIG. 2).

The scan lines S₀ to Sn′ include forward scan lines S₀ to Sn and reverse scan lines S₀′ to Sn′ that are disposed to be continuously alternating with the forward scan lines.

One of the first and second electrodes may be connected to one of the forward scan lines S₀ to Sn and the other may be connected to one of the reverse scan lines S₀′ to Sn′ and the intermediate electrode may be connected to one of the data lines.

The first and second sub-pixels may be individually driven by one data line.

The power supply module may supply a voltage (VDD) used for a logic power supply, a voltage (VCC) used for a driving power supply, and a reference voltage (Vref) to the data driver, the scan driver, and the controller.

In this case, the VDD is a logic power supply, and the VCC is an analog power supply of the scan driver and the data driver.

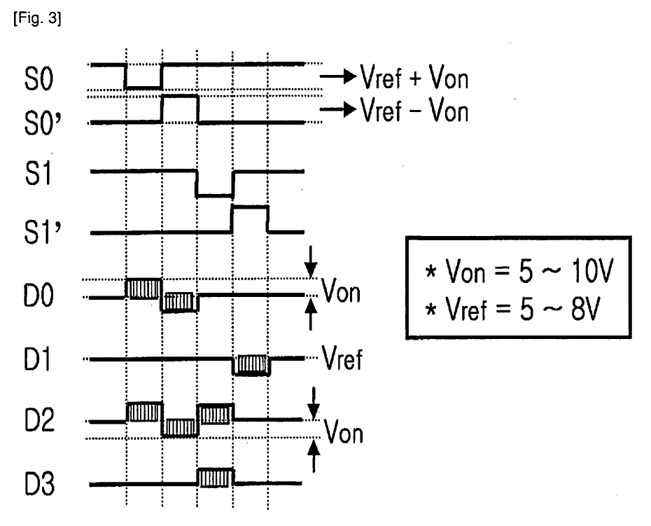

The data lines may maintain the reference voltage (Vref) in an OFF state. In an ON state, the data lines swing between a summation voltage (Vref+Von) between the reference voltage (Vref) and a voltage (Von) applied to the data lines in accordance with scan directions of the scan lines and a subtraction voltage (Vref−Von) between the reference voltage (Vref) and the voltage (Von) applied to the data lines so as to control the stacked first and second sub-pixels (refer to FIG. 3).

At the time of scanning the n-th scan line among the forward scan lines S₀ to Sn, data may be controlled by the summation voltage (Vref+Von), and a corresponding sub-pixel of the stacked first and second sub-pixels may be controlled by the subtraction voltage (Vref−Von) at the time of scanning the n′-th scan line among the reverse scan lines S₀′ to Sn′ (refer to FIGS. 2 and 3). In this case, the n and n′ are natural numbers.

A light-emitting color of the first sub-pixel may be any one of R (Red), G (Green), B (Blue), and W (White), and a light-emitting color of the second sub-pixel may be any one of R (Red), G (Green), B (Blue), and W (White).

On the basis of a pair of stacked organic light-emitting diode having first sub-pixel and second sub-pixel, the number of combinations of light-emitting colors of a total of four sub-pixels may be 24.

That is, the number of combinations of light-emitting colors of four sub-pixels that includes first and second sub-pixels of one stacked organic light-emitting diode and first and second sub-pixels of another stacked organic light-emitting diode may be 24.

A combination of light-emitting colors of four sub-pixels may be RGBW, RGWB, RWGB, RWBG, RBWG, RBGW, GRBW, GRWB, GBRW, GBWR, GWRB, GWBR, BRGW, BRWG, BRWG, BGRW, BGWR, BWRG, BWGR, WRGB, WRBG, WGRB, WGBR, WBRG, or WBRG.

Further, on the basis of a pair of stacked organic light-emitting diode having first sub-pixel and second sub-pixel, the number of combinations of light-emitting colors of a total of four sub-pixels may be 36.

That is, a combination of light-emitting colors of four sub-pixels may be RRGB, RRBG, RGRB, RGBR, RBGR, RBRG, GRRB, GRBR, GBRR, BRRG, BRGR, BGRR, GGRB, GGBR, GRGB, GRBG, GBRG, GBGR, RGGB, RGBG, RBGG, BGGR, BGRG, BRGG, BBRG, BBGR, BRBG, BRGB, BGRB, BGBR, RBBG, RBGB, RGBB, GBBR, GBRB or GRBB.

An organic light-emitting display apparatus that includes a plurality of stacked organic light-emitting diodes (SOLED) according to the present invention may be a passive-matrix organic light-emitting display apparatus.

Further, the organic light-emitting display apparatus that includes a plurality of stacked organic light-emitting diodes (SOLED) according to the present invention may be an active-matrix organic light-emitting display apparatus.

In the structure of the passive-matrix organic light-emitting display apparatus that includes stacked organic light-emitting diodes each having stacked first and second sub-pixels, the sub-pixels may be arranged in two types. For example, the sub-pixels may be arranged in a structure of RG, BW, RG, BW . . . and a structure of RB, GB, RB, GB . . . . However, the present invention is not limited thereto.

Referring to the first structure, RG sub-pixels are stacked on a first data line, BW sub-pixels are stacked on a second data line, and RG sub-pixels are stacked on a third data line. In this way, two sub-pixels can be controlled by the same data line. The first structure is a pixel structure that is used to reduce white power consumption.

In the case of the first structure, at a white grade, according to a method of controlling a W sub-pixel instead of a combination of RGB sub-pixels, as compared with the combination of RGB sub-pixels, power consumption reduction of 66% can be achieved. In this case, the controller preferably includes a module that controls each W sub-pixel.

The second structure is not limited to a structure of RB, GB, RB, GB . . . . This structure is a method in which sub-pixels having a short life span or low efficiency among RGB sub-pixels overlap and are driven for every sub-pixel, and is a structure that can achieve various configurations of organic light-emitting display apparatuses according to combinations thereof.

The organic light-emitting display apparatus according to the present invention may be used as a display apparatus that displays images in electronic products, such as, for example, a TV, a monitor, a mobile phone or a portable multimedia apparatus.

Meanwhile, a method of driving an organic light-emitting display apparatus according to another embodiment of the present invention is a method of driving an organic light-emitting display apparatus that allows stacked organic light-emitting diodes each having two sub-pixels, which are stacked, to emit light by a scan driver and a data driver. The scan driver outputs scan line driving signals to sequentially select scan lines, and the data driver outputs data line driving signals to output data of the selected scan lines to the data lines. In this method, the two sub-pixels, which are stacked, are individually driven by one data line. Of course, the contents according to the above-described embodiment are applied to this embodiment.

According to the method of driving an organic light-emitting display apparatus according to the present invention, when the stacked organic light-emitting diodes each having two sub-pixels which are stacked, are driven by the scan driver and the data driver, the two sub-pixels, which are stacked, may be individually driven by one data line. For example, the two sub-pixels, which are stacked, may be driven such that one operates by a forward bias and the other operates by a reverse bias.

### Mode for the Invention

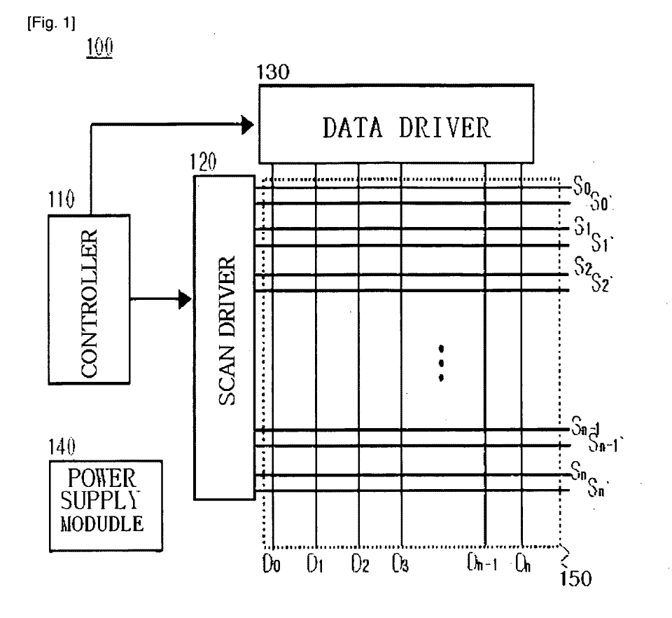

FIG. 1 is a diagram illustrating an organic light-emitting display apparatus that includes stacked organic light-emitting diodes in accordance with the present invention. Specifically, FIG. 1 is a diagram illustrating an example of a driving module 100 that drives a passive-matrix stacked organic light-emitting diode (PMSOLED) panel 150 that includes stacked organic light-emitting diodes (SOLED).

As shown in FIG. 1, the driving module 100 that drives the PMSOLED panel 150 as the organic light-emitting display apparatus according to the present invention includes a controller 110 that controls driving, a scan driver 120, a data driver 130, and a power supply module 140.

The controller 110 controls the scan driver 120 and the data driver 130 such that data according to individual scan timings is transmitted to the PMSOLED panel 150 to display an image on the PMSOLED panel 150, and allows accurate timing and image data suitable for the structure of the PMSOLED panel 150 to be generated.

The power supply module 140 is connected to the controller 110, the scan driver 120, and the data driver 130. The power supply module 140 supplies a voltage (VDD) used for a logic power supply, a voltage (VCC) used for a driving power supply, and a reference voltage (Vref) to the controller 110, the scan driver 120, and the data driver 130.

In this case, the VDD is a logic power supply, and the VCC is an analog power supply of the scan driver 120 and the data driver 130.

The scan driver 120 and the data driver 130 generate scan timing necessary for driving and actual image data of the PMSOLED panel 150, and an example of timing is shown in FIG. 3.

The PMSOLED panel 150 shown in FIG. 1 that is driven by the driving module 100 shown in FIG. 1 has a type in which stacked organic light-emitting diodes each having a structure where first and second sub-pixels overlap are arranged, and a specific structure of the PMSOLED panel is shown in FIG. 2.

FIG. 2 is a diagram illustrating an example of a PMSOLED panel 150 that has a structure in which stacked organic light-emitting diodes (SOLED) each having first and second sub-pixels are arranged on a substrate. However, the present invention is not limited to the structure shown in FIG. 2.

As can be seen from FIG. 2, S0, S1, . . . , and Sn are forward scan lines for forward scanning and S0′, S1′, . . . , and Sn′ are reverse scan lines for reverse scanning. At the selected scan portions, data of the data lines D1, . . . , and Dn are sequentially made in forward and backward directions, and the stacked first and second sub-pixels may be driven by one data line.

At this time, as shown in FIG. 2, when the arrangement of sub-pixels is the structure of RGBWRGBW . . . RGBW on the scan lines S0 and S0′, sub-pixels 201, 203, . . . are stacked in the arrangement of RG sub-pixels and sub-pixels 202, 204, . . . are stacked in the arrangement of BW sub-pixels, which reproduces a full color.

In the structure of RBGBRBGB . . . RBGB, the sub-pixels 201, 203, . . . are stacked in the arrangement of RB sub-pixels and the sub-pixels 202, 204, . . . are stacked in the arrangement of GB sub-pixels.

At this time, RBGB sub-pixels may be stacked according to each combination, such as RGBG or GRBR, if necessary. As shown in FIG. 2, the same stack method may be applied to the sub-pixels 211, 212, 213, 214, . . . formed on the scan lines S1 and S1′ and the sub-pixels may be stacked.

FIG. 3 is a diagram illustrating timings of data lines (D₀ to Dn) and scan lines (S₀ to Sn′) of turned-on pixels (bright pixels denoted by reference numeral 200) in FIG. 2.

In order to effectively drive the PMSOLED panel 150, the timings of data lines (D₀ to Dn) and scan lines (S₀ to Sn′) may be as shown in FIG. 3.

In an OFF state, the data lines D₀ to Dn maintain the reference voltage Vref. At the time of writing data, that is, in an ON state, the data lines D₀ to Dn swing between the voltage (Vref+Von) and the voltage (Vref−Von) shown in FIG. 3 according to each scan direction so as to control the stacked first and second sub-pixels. In FIG. 3, the reference voltage (Vref) is in a range of 5 to 8 V, and the voltage Von is in a range of 5 to 10 V. These voltage conditions may vary according to characteristics of sub-pixels.

For example, at the time of scanning the Sn-th scan line shown in FIG. 2, data is the voltage (Vref+Von) shown in FIG. 3 and the sub-pixels can be minutely controlled. At the time of scanning the Sn′-th scan line shown in FIG. 2, data is the voltage (Vref−Von) shown in FIG. 3 and the corresponding sub-pixels can be minutely controlled. At this time, the data may be driven in pulse width modulation (PWM) and pulse amplitude modulation (PAM) methods.

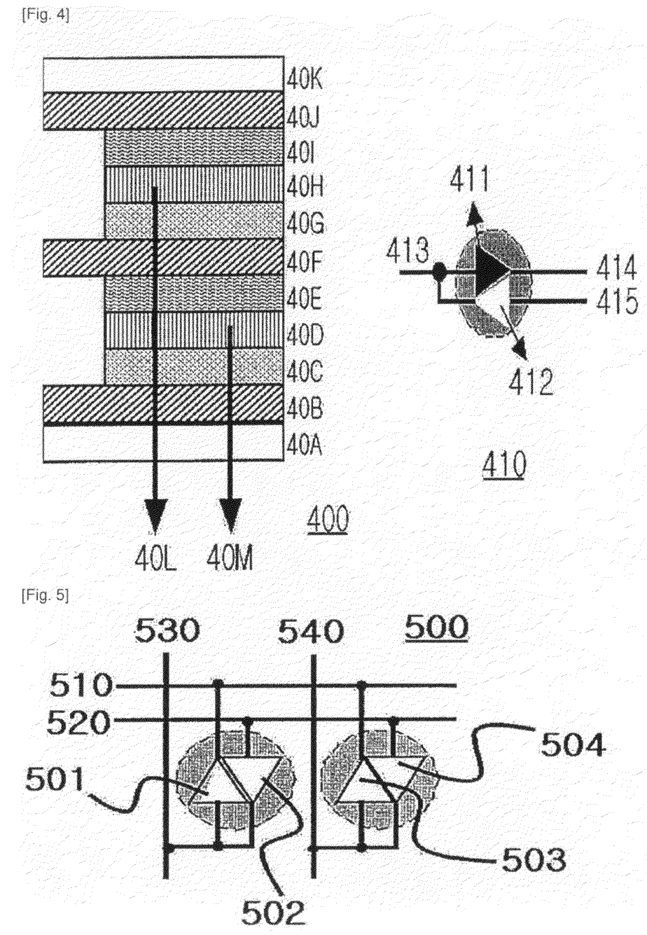

FIG. 4 is a diagram illustrating a structure of a stacked organic light-emitting diode that has first and second sub-pixels.

As shown in FIG. 4, in the case of a stacked organic light-emitting diode 400, two sub-pixels 411 and 412 have a stacked structure to be biased in different directions.

A line 413 that is connected to an intermediate electrode 40F of the stacked organic light-emitting diode 400 is connected to the data line Dn shown in FIG. 2, and lines 414 and 415 that are connected to first and second electrodes 40B and 40J are connected to the scan lines Sn and Sn′ shown in FIG. 2. The two sub-pixels 411 and 412 may be controlled to be individually driven at timings shown in FIG. 3.

The structure of the stacked organic light-emitting diode 400 will be described in detail. A plurality of layers are stacked between first and second transparent substrates 40A and 40K to form first and second sub-pixels 40M and 40L.

A structure for displaying a light-emitting color of the first sub-pixel 40M includes a first transparent electrode 40B, a hole injecting layer (HIL)/hole transporting layer (HTL) 40C, an emitting layer (EML) 40D, an electron transporting layer (ETL) 40E, and an intermediate transparent electrode 40F.

A structure for displaying a light-emitting color of the second sub-pixel 40L includes an intermediate transparent electrode 40F, a hole injecting layer (HIL)/hole transporting layer (HTL) 40G, an emitting layer (EML) 40H, an electron transporting layer (ETL) 40I, and a second transparent electrode 40J.

In this case, the intermediate transparent electrode 40F is connected to the data line Dn shown in FIG. 2 and used as a data electrode, and the other first and second transparent electrodes 40B and 40J are connected to the scan lines Sn and Sn′ shown in FIG. 2. Accordingly, the stacked first and second sub-pixels 40M and 40L may be individually driven by one data line Dn.

In order to display full-color information, for example, as shown in FIG. 5, the organic light-emitting display panel 500 can be configured by a combination of sub-pixels of RGBW or RBGB.

As shown in FIG. 5, a variety of color information may be displayed by a combination of first and second sub-pixels 503 and 504, which is different from a combination of stacked first and second sub-pixels 501 and 502. As described above, the combinations of the sub-pixels may be mainly divided into a structure of RGBW and a structure of RBGB and the organic light-emitting display panel 500 may be configured.

In the case of the structure of the RGBW sub-pixels, the sub-pixels may be stacked in the arrangement of R(501)/G(502) and B(503)/W(504). This method has an advantage in that a W sub-pixel is used and thus power consumption can be greatly reduced.

In the case of the structure of the RBGB sub-pixels, the sub-pixels may be stacked in the arrangement of R(501)/B(502) and G(503)/B(504). This method is a method in which a B sub-pixel is used once more. Specifically, in this method, among the three R, G, and B sub-pixels, a sub-pixel that is needed to increase a life span and efficiency is repeatedly used.

Accordingly, it is possible to improve characteristics of the sub-pixels by various combinations of sub-pixels, such as a combination of RBGB sub-pixels, a combination of GRBR sub-pixels, and a combination of RGBG.

As such, according to the present invention, it is possible to implement a full color of a glass light-emitting display panel on the basis of stacked organic light-emitting diodes each having two sub-pixels. Further, the glass light-emitting display panel can be effectively driven.

1. An organic light-emitting display apparatus comprising:
a substrate;
scan lines and data lines that are formed on the substrate to cross with each other;
stacked organic light-emitting diodes that are connected to the scan lines and the data lines on the substrate and each have two sub-pixels which are stacked, wherein the two stacked sub-pixels are individually driven by one data line;
a data driver that is connected to the data lines and applies data signals to the data lines;
a scan driver that is connected to the scan lines and applies scan signals to the scan lines;
a controller that controls the data driver and the scan driver; and
a power supply module that supplies a power supply voltage to the data driver, the scan driver, and the controller.

2. The organic light-emitting display apparatus of claim 1,
wherein each of the stacked organic light-emitting diodes comprise the two sub-pixels, which are stacked, having a first electrode, a second electrode, an intermediate electrode located between the first and second electrodes, a first organic material layer located between the first electrode and the intermediate electrode, and a second organic material layer located between the intermediate electrode and the second electrode.

3. The organic light-emitting display apparatus of claim 2,
wherein each of the first organic material layer and the second organic material layer comprises a hole injecting layer, a hole transporting layer, an light-emitting layer, and an electron transporting layer.

4. The organic light-emitting display apparatus of claim 1,
wherein one of the two sub-pixels, which are stacked, operates by a forward bias and the other operates by a reverse bias.

5. The organic light-emitting display apparatus of claim 2,
wherein the scan lines S₀ to Sn′ comprise forward scan lines S₀ to Sn and backward scan lines S₀′ to Sn′ that are disposed to be continuously alternating with the forward scan lines,
one of the first and second electrodes is connected to one of the forward scan lines S₀ to Sn, and the other is connected to one of the backward scan lines S₀′ to Sn′, and
the intermediate electrode is connected to one of the data lines.

6. The organic light-emitting display apparatus of claim 1,
wherein a light-emitting color of each of the two sub-pixels, which are stacked, is one of R (Red), G (Green), B (Blue), and W (White).

7. The organic light-emitting display apparatus of claim 6,
wherein, on the basis of a pair of stacked organic light-emitting diodes each having the two sub-pixels, which are stacked, a combination of light-emitting colors of four sub-pixels is RGBW, RGWB, RWGB, RWBG, RBWG, RBGW, GRBW, GRWB, GBRW, GBWR, GWRB, GWBR, BRGW, BRWG, BGRW, BGWR, BWRG, BWGR, WRGB, WRBG, WGRB, WGBR, WBRG, or WBRG.

8. The organic light-emitting display apparatus of claim 6,
wherein, on the basis of a pair of stacked organic light-emitting diodes each having the two sub-pixels, which are stacked, a combination of light-emitting colors of four sub-pixels is RRGB, RRBG, RGRB, RGBR, RBGR, RBRG, GRRB, GRBR, GBRR, BRRG, BRGR, BGRR, GGRB, GGBR, GRGB, GRBG, GBRG, GBGR, RGGB, RGBG, RBGG, BGGR, BGRG, BRGG, BBRG, BBGR, BRBG, BRGB, BGRB, BGBR, RBBG, RBGB, RGBB, GBBR, GBRB or GRBB.

9. The organic light-emitting display apparatus of claim 1,
wherein the power supply module supplies a voltage (VDD) for a logic power supply, a voltage (VCC) for a driving power supply, and a reference voltage (Vref) to the data driver, the scan driver, and the controller, respectively.

10. The organic light-emitting display apparatus of claim 1,
wherein, in an OFF state, the data lines maintain a reference voltage (Vref), and
in an ON state, the data lines swing between a summation voltage (Vref+Von) between the reference voltage (Vref) and a voltage (Von) applied to the data lines and a subtraction voltage (Vref−Von) between the reference voltage (Vref) and the voltage (Von) applied to the data lines according to individual scan directions of the scan lines so as to control the two sub-pixels which are stacked.

11. The organic light-emitting display apparatus of claim 10,
wherein the scan lines S₀ to Sn′ comprise forward scan lines S₀ to Sn and backward scan lines S₀′ to Sn′ that are disposed to be continuously alternating with the forward scan lines,
the two sub-pixels, which are stacked, are controlled by the summation voltage (Vref+Von) at the time of scanning the n-th scan line among the forward scan lines S₀ to Sn and the subtraction voltage (Vref−Von) at the time of scanning the n′-th scan line among the backward scan lines S₀′ to Sn′, and
the n and n′ are natural numbers.

12. The organic light-emitting display apparatus of claim 1,
wherein the organic light-emitting display apparatus is a passive-matrix organic light-emitting display apparatus.

13. The organic light-emitting display apparatus of claim 1,
wherein the organic light-emitting display apparatus is an active-matrix organic light-emitting display apparatus.

14. An electronic product comprising the organic light-emitting display apparatus of claim 1.

15. The electronic product of claim 14,
wherein the electronic product is a TV, a monitor, a mobile phone or a portable multimedia apparatus.

16. A method of driving an organic light-emitting display apparatus that allows stacked organic light-emitting diodes each having the two sub-pixels, which are stacked, to emit light by a scan driver outputting scan line driving signals for sequentially selecting scan lines and a data driver outputting data line driving signals for outputting data of the selected scan lines to the data lines,
wherein the two sub-pixels, which are stacked, are individually driven by one data line.

17. The method of claim 16,
wherein, when the two sub-pixels, which are stacked, are individually driven by one data line, one of the two sub-pixels, which are stacked, operates by a forward bias and the other operates by a reverse bias.

18. The method of claim 16,
wherein each of the stacked organic light-emitting diodes comprise the two sub-pixels, which are stacked, having a first electrode, a second electrode, an intermediate electrode located between the first and second electrodes, a first organic material layer located between the first electrode and the intermediate electrode, and a second organic material layer located between the intermediate electrode and the second electrode.

19. The method of claim 18,
wherein the scan lines S₀ to Sn′ comprise forward scan lines S₀ to Sn and backward scan lines S₀′ to Sn′ that are disposed to be continuously alternating with the forward scan lines,
one of the first and second electrodes is connected to one of the forward scan lines S₀ to Sn, and the other is connected to one of the backward scan lines S₀′ to Sn′, and
the intermediate electrode is connected to one of the data lines, and the two sub-pixels, which are stacked, are individually driven by one data line.

20. The method of claim 16,
wherein, when the two sub-pixels, which are stacked, are driven, a light-emitting color of each of the two sub-pixels, which are stacked, is one of R (Red), G (Green), B (Blue), and W (White), and
on the basis of a pair of stacked organic light-emitting diodes each having the two sub-pixels, which are stacked, a combination of light-emitting colors of four sub-pixels is RGBW, RGWB, RWGB, RWBG, RBWG, RBGW, GRBW, GRWB, GBRW, GBWR, GWRB, GWBR, BRGW, BRWG, BGRW, BGWR, BWRG, BWGR, WRGB, WRBG, WGRB, WGBR, WBRG, or WBRG.

21. The method of claim 16,
wherein, when the two sub-pixels, which are stacked, are driven, a light-emitting color of each of the two stacked sub-pixels is one of R (Red), G (Green), B (Blue), and W (White), and
on the basis of a pair of stacked organic light-emitting diodes having the two sub-pixels, which are stacked, a combination of light-emitting colors of four sub-pixels is RRGB, RRBG, RGRB, RGBR, RBGR, RBRG, GRRB, GRBR, GBRR, BRRG, BRGR, BGRR, GGRB, GGBR, GRGB, GRBG, GBRG, GBGR, RGGB, RGBG, RBGG, BGGR, BGRG, BRGG, BBRG, BBGR, BRBG, BRGB, BGRB, BGBR, RBBG, RBGB, RGBB, GBBR, GBRB or GRBB.

22. The method of claim 16,
wherein, in an OFF state, the data lines maintain a reference voltage (Vref), and
in an ON state, the data lines swing between a summation voltage (Vref+Von) between the reference voltage (Vref) and a voltage (Von) applied to the data lines and a subtraction voltage (Vref−Von) between the reference voltage (Vref) and the voltage (Von) applied to the data lines according to individual scan directions of the scan lines so as to control the two sub-pixels, which are stacked.

23. The method of claim 22,
wherein the scan lines S₀ to Sn′ comprise forward scan lines S₀ to Sn and backward scan lines S₀′ to Sn′ that are disposed to be continuously alternating with the forward scan lines,
the two sub-pixels, which are stacked, are controlled by the summation voltage (Vref+Von) at the time of scanning the n-th scan line among the forward scan lines S₀ to Sn and the subtraction voltage (Vref−Von) at the time of scanning the n′-th scan line among the backward scan lines S₀′ to Sn′, and
the n and n′ are natural numbers.
